(19) United States
(12) Patent Application Publication
(10) Pub. No.: US 2015/0007773 A1
(43) Pub. Date: Jan. 8, 2015

(54) CO2 RECYCLING DEVICE AND CO2 RECYCLING SYSTEM

(71) Applicant: T-SUPPORT CO., LTD., Osaka (JP)

(72) Inventors: Akihiko Toyoshima, Osaka (JP); Nobuo Ohmae, Hyogo (JP)

(73) Assignee: T-SUPPORT CO., LTD., Osaka (JP)

(21) Appl. No.: 14/377,266

(22) PCT Filed: May 27, 2013
(86) PCT No.: PCT/JP2013/003345

§ 371 Date: Aug. 7, 2014

(30) Foreign Application Priority Data
May 25, 2012 (JP) 2012-120000

(51) Int. Cl. C23C 16/511

(52) U.S. Cl. CPC C23C 16/511
USPC 118/723 MW

(57) ABSTRACT

To provide a CO₂ recycling device which is compact and with which electricity consumption can be reduced. The invention is a device for manufacturing multilayer carbon nanotubes, carbon onions or nano-carbons, using a microwave plasma CVD method, taking the CO₂ gas within a carbon monoxide-containing gas as the carbon source. The device comprises a microwave oscillator, a microwave waveguide and a reaction tube provided within the microwave waveguide, and a gas inlet pipe and an exhaust pipe are configured from the reaction tube which returns within the microwave waveguide and a ceramic-type heater provided on the inner wall of the gas inlet pipe. Then, microwave plasma is generated at the position where the reaction tube returns, and the multilayer carbon nanotube, carbon onion or nano-carbon formed is adhered to the inner wall of the exhaust pipe.

### TECHNICAL FIELD

The present invention is concerned with the apparatus and system which reduce the amount of carbon dioxide (CO₂) from the exhaust gas of automobiles and ships by solidifying carbon (C), and further the synthesis of such value-added advanced carbon materials as carbon nanotube (CNT), carbon onion, carbon nanohorn, etc.

### BACKGROUND ART

It is generally well accepted that the decomposition of carbon dioxide (CO₂) is much harder than carbon monoxide (CO) and hydrocarbons (HC), because the energy required for decomposing CO₂ is very high.

Under these circumstances, Ohmae invented and proposed the CO₂ recycling apparatus which synthesized either multi-walled carbon nanotube, carbon onion and/or other nano-carbons by decomposing carbon dioxide (CO₂ gas) with microwave plasma CVD (patent literatures 1).

The CO₂ recycling apparatus proposed earlier was equipped with the substrate on which catalyst such as iron was deposited, the heating system which heat the substrate, gas introduction which introduced CO₂ gas to the surface of substrate, microwave plasma generator which ignited microwave plasma on the substrate surface, and the power supply which supplied electric power to the microwave plasma generator.

[Patent literature 1] International Publication Pamphlet WO 2011/004609 A1

### OUTLINE OF THE INVENTION

### Problems to be Solved by the Invention

The above stated CO₂ recycling apparatus, now under proposing, composed of microwave plasma generator and muffle furnace around the quartz tube with a length of 800 mm, and the nano-carbons were deposited on the surface of substrate placed in the furnace by decomposing CO₂ gas with hydrogen (H₂) as a carrier gas. Thus the apparatus under proposing had the problem of increased electricity consumption, because the sum of electric consumption of microwave generator and muffle furnace became large.

In addition, the large dimension of apparatus was another problem, because one of the major components was the quartz tube with the length of 800 mm.

From these viewpoints, the present invention aims the establishment of CO₂ recycling apparatus with the compact size and low electricity consumption.

### Means to Solve the Objects

To solve the above problems, the present inventors accomplished the CO₂ recycling apparatus with many trial and errors.

The newly invented CO₂ recycling apparatus synthesizes either multi-wall carbon nanotube, carbon onion or other nano-carbons using CO₂ gas contained in hydrocarbon gases with a use of microwave plasma CVD, and is composed of the major components shown below.

### 1) Microwave Generator

The magnetron in commercially available microwave oven, 2.45 GHz frequency and 500 W maximum power, is applicable to the microwave generator.

### 2) Microwave Guide

Microwave is resonated by the back and force of microwave.

### 3) Reaction Tube

Reaction tube is installed in the microwave guide, and gas inlet and vacuum evacuation are folded back in this reaction tube. By this design, the length of quartz tube can be shortened, and the apparatus becomes compact.

It is advantageous to increase the path of gas flow. Therefore, spiral shaped tube or zigzag tube seems applicable.

### 4) Ceramics Heater Stored Inside of Gas Inlet

With this ceramics heater, the temperature is increased by the irradiation of microwave. The ceramics heater is needed mainly for depositing nano-carbons from CO₂ gas. However, the influence of ceramics heater on the reduction rate of CO₂ gas is small.

With major components shown above, microwave plasma is generated in the reaction tube to deposit multi-wall carbon nanotube, carbon onion or other nano-carbons at the wall of reaction tube. The carbons can be deposited on the surface of substrate by putting such substrate in the reaction tube.

Moreover, plasma CVD is effective in decomposing fluorocarbon gases or other toxic gases, and the present CO₂ recycling apparatus can be used in order to decompose hydrocarbon gases containing fluorocarbon or other toxic gases.

The CO₂ recycling apparatus also works by using coaxial microwave cable instead of microwave guide, and the microwave plasma generates at the reaction tube connected to this coaxial microwave cable.

In other words, the present CO₂ recycling apparatus synthesizes multi-wall carbon nanotube, carbon onion or other nano-carbons from CO2 gas contained in hydrocarbon gases by the microwave plasma CVD, and is equipped with microwave generator, microwave coaxial cable, and the reaction tube connected to the coaxial cable. The plasma is maintained in the reaction tube where gas inlet and vacuum evacuation are turned back. The present CO₂ recycling apparatus contains ceramics heater inside of the gas inlet.

The reaction tube described in the present invention typically is the U-shaped quartz tube, and one end is connected to the gas inlet, while the other to vacuum evacuation.

By this design, the length of quartz tube can be shortened, and the apparatus becomes compact.

It is advantageous to increase the path of gas flow. Therefore, spiral shaped tube or zigzag tube seems applicable.

Other type of reaction tube in the present invention is the quartz tube with different diameters, and the tube with smaller diameter is connected to gas inlet, while the one with larger diameter to vacuum evacuation.

By putting gas inlet tube in the vacuum evacuation tube, the limitation of the length of quartz tube is set free. Therefore, the present apparatus becomes compact.

It is advantageous to increase the path of gas flow. Thus, spiral shaped tube or zigzag tube seems applicable.

The ceramics heater in the present invention is made of silicon carbide (SiC).

This kind of ceramics heater is heated by the irradiation of microwave plasma. As a result, the electric power for furnace or other heaters is unnecessary, and the electricity power consumption is lowered. The ceramics heater is needed mainly for depositing nano-carbons from CO₂ gas. However, the influence of ceramics heater on the reduction rate of CO₂ gas is small.

The pressure in the reaction tube in this CO₂ recycling apparatus is 100˜200 Pa. When the pressure is lower than 100 Pa, or when the pressure is higher than 200 Pa, microwave plasma hardly ignites. It is known that plasma generation does not take place when the pressure is too low or too high.

The reaction tube in the present invention can be chosen from transparent quartz, non-transparent quartz, ceramics and metals. Particularly, transparent quartz tube is frequently used. Transparent quartz is refined from natural quartz by heating up at about 1800° C., and then this ingot is formed in the shape of U in the electric furnace at about 2000° C. using graphite as a mold. Non-transparent quartz is made from silica rocks, and the bubbles in bulk material are incorporated. Thus the quartz becomes non-transparent. It is possible to use ceramics and metals as the reaction tube. The reaction tube made from transparent quartz, non-transparent quartz, ceramics or metals functions as the location of deposition of multi-wall carbon nanotube, carbon onion or other nano-carbons by the microwave plasma CVD.

It is favorable that the microwave guide proposed in this CO₂ recycling apparatus has the length of smaller than 400 mm, the width of smaller than 200 mm, and the height of smaller than 100 mm. At the center of the above mentioned microwave guide, the folding back position of reaction tube is positioned so as to generate microwave plasma.

The present inventors succeeded in building the microwave guide with the length of smaller than 400 mm, the width of smaller than 200 mm, and the height of smaller than 100 mm by many trials and errors. Small size of wave guide results in saving electric power consumption. It is possible to create the CO₂ recycling system by using multiple numbers of CO₂ recycling apparatus.

In the present CO₂ recycling apparatus, the microwave guide should have a microwave matching device, and the coaxial microwave cable should have a coaxial three stub tuner.

The CO₂ recycling system described in the present invention is the system that uses multiple CO₂ recycling apparatus, and in this case the vacuum evacuation part of one apparatus is connected to the gas inlet part of the other apparatus. By connecting multiple CO₂ recycling apparatus, the reduction rate of CO₂ becomes high. When the big CO₂ recycling apparatus is needed, namely, when the amount of CO₂ gas is large, the parallel use of multiple CO₂ recycling apparatus is favored. By aligning the gas inlets of multiple CO₂ recycling apparatus in a parallel way, and dividing the gas flow from a large duct into small tubes, CO₂ gas from each small tube is processed by each CO₂ recycling apparatus.

In the present CO₂ recycling system, it is desired that the residual gas after removing carbon monoxide in the first CO₂ recycling apparatus should be introduced to the next CO₂ recycling apparatus. Carbon monoxide gas removed from the evacuation tube of CO₂ recycling apparatus can be re-used as a fuel. CO₂ gas derived from combusting CO is decomposed and reduced by the present CO₂ recycling apparatus.

### Effects of the Invention

The present CO₂ recycling apparatus effectively solidifies carbon (C) in CO₂ gas, and the electricity consumption is reduced by down-sizing the apparatus.

In addition, this CO₂ recycling apparatus utilizes plasma CVD, so that this method can be extended to fluorocarbon gas and other toxic gases.

### BRIEF DESCRIPTION OF THE DRAWINGS

FIG. 1 shows the block diagram of the CO₂ recycling apparatus of the present invention.

FIG. 2 shows the block diagram of the CO₂ recycling apparatus of embodiment 1 (plan view).

FIG. 3 shows the block diagram of the CO₂ recycling apparatus of embodiment 1 (front view).

FIG. 4 shows the block diagram of the CO₂ recycling apparatus of embodiment 2 (plan view).

FIG. 5 shows the block diagram of the CO₂ recycling apparatus of embodiment 2 (front view).

FIG. 6 shows the graph showing correlation between input energy and CO₂ decomposition rate.

FIG. 7 shows the graph showing correlation between input energy and CO₂ dissociation rate.

FIG. 8 shows the graph showing correlation between input energy and equipment efficiency.

FIG. 9 shows the graph showing correlation between gas composition and CO₂ decomposition rate.

### BEST MODE FOR CARRYING OUT THE INVENTION

Embodiments of the present invention will be described in detail below with reference to the drawings. The present invention is not limited to the following embodiment and examples of shown in the figure, and the present invention can be variously changed in design.

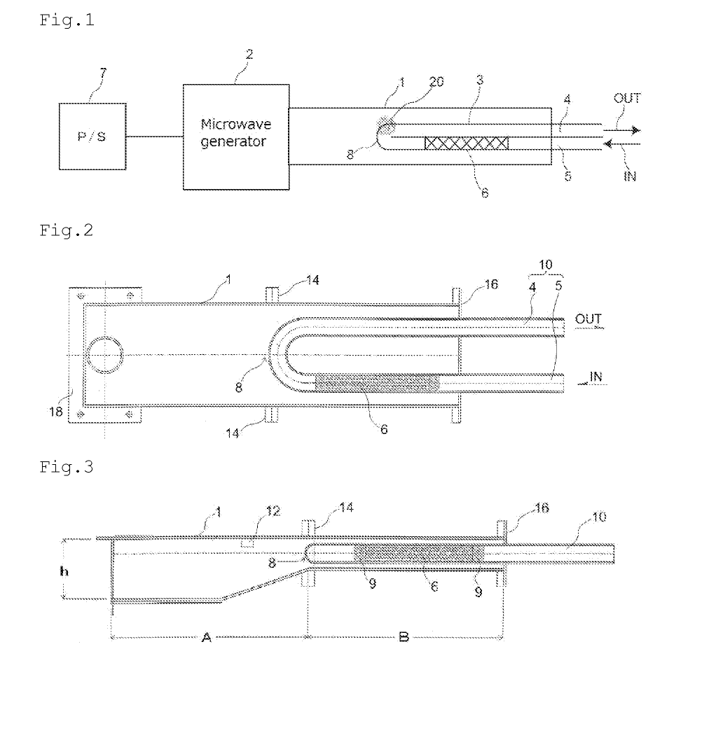

FIG. 1 shows the block diagram of the CO₂ recycling apparatus of the present invention. The present CO₂ recycling apparatus has the microwave guide 1, microwave generator 2 and reaction tube 3 which is installed in microwave guide 1. The reaction tube 3 is composed of gas inlet tube 5 and vacuum evacuation tube 4, and the gas flow in the reaction tube is turned back at the point 8. Inside the gas inlet, ceramics heater 6 is equipped.

Microwave is resonated in the microwave guide 1 by putting on the microwave generator 2, microwave plasma 20 originates at the point 8 where the gas flow is turned back. Microwave generator 2 functions by the power supply 7. Power supply 7 is 100V table tap for general family use, for example. CO₂ gas is introduced from outer part of microwave guide 1 to gas inlet 5, turned back at the position 8 in the reaction tube 3, and evacuated from vacuum evacuation tube 4 after passing the location of microwave plasma 20. By designing gas flow in tubes 5 and 4, the length of reaction tube is shortened, and consequently the apparatus becomes compact.

Ceramics heater is stored in the inner wall of gas inlet where the microwave guide surrounds, and is heated by the microwave irradiation. CO₂ gas which flows in the gas inlet 5 is heated when it flows near the ceramics heater 6. Near the location of folding back point 8, multi-wall carbon nanotube, carbon onion or nano-carbons are synthesized. Multi-wall carbon nanotube, carbon onion and/or other nano-carbons are deposited on the inner wall of vacuum evacuation tube.

Because the ceramics heater 6 is heated by the irradiation of microwave generated from the microwave generator 2, additional heaters are unnecessary. Therefore, the total electric energy consumption is determined only by the one from the microwave generator 2, and consequently the electric energy consumption becomes small.

In the below enforced embodiments, the shapes of reaction tubes, the relation between energy consumption and the amount of synthesized carbon nanotube, carbon onion and nano-carbon, the amount of CO₂ decomposition are made clear, and the effect of CO₂ decomposition of the present apparatus is quantitatively explained.

### Embodiment 1

Embodiment 1 shows the CO₂ recycling apparatus with the U-shaped reaction tube. FIGS. 2 and 3 indicate horizontal and front views of the above CO₂ recycling apparatus, respectively.

As shown in the horizontal view (FIG. 2), the microwave guide 1 is a rectangular box when viewed from vertical position, and the U-shaped tube 10 is inserted to the center of 1. As shown in the front view (FIG. 3), the height of microwave guide 1 at the opposite position to the location of U-shaped tube 10 is high (cross sectional area is large), and the cross sectional area becomes small near the location of 10. From the left-hand side to the center of FIG. 3, the height becomes small and is constant at the right-hand side. Here let h, A and B the height at left-hand side, the distance from the center to the left end, and the distance from the center to the right-hand end, respectively. A and B are almost the same, and actually about 189 mm. h is approximately 50 mm.

In FIGS. 2 and 3, the microwave generator is placed near the right-hand side of microwave guide 1, but not shown in the figures.

U-shaped tube 10 is placed inside of the microwave guide 1. The U-shaped tube is folded back near the center between gas inlet 5 and vacuum evacuation 4. Ceramics heater 6 is placed inside the gas inlet 5. At the both sides of ceramics heater 6, ceramics fibers are molded. The material of ceramics heater is silicon carbide (SiC).

At the position of folding back of the U-shaped tube 10, i.e., 8, microwave plasma generates. For adjusting the resonance and tuning the conditions of microwave plasma generation, microwave matching device 12 is fitted (see FIG. 3).

By the microwave plasma of CO₂ gas, multi-wall carbon nanotube, carbon onion and/or nano-carbon are deposited on the inner wall of vacuum evacuation tube 4 of the U-shaped tube 10. These deposits are derived from the solidification of carbon (C) contained in the CO₂ gas. Thus, the exhausted gas from the vacuum evacuation tube has less content of CO₂ than the one introduced from gas inlet tube 5.

The reduction amount and the rate of reduction of CO₂ are explained.

Table 1 tabulates the relation between electric power and the reduction rate of CO₂, when CO₂ was decomposed by microwave plasma CVD to deposit solid carbons on the inner wall of vacuum evacuation tube 4 of U-shaped tube 10. The introduced gases from gas inlet 5 of U-shaped tube 10 were 20 sccm of CO₂ and 80 sccm of H₂ (carrier gas).

TABLE 1

| Input power [W] | CO₂ decomposition rate [%] |
|---|---|
| 100 | 68.5 |
| 150 | 73.0 |
| 200 | 81.0 |
| 250 | 83.0 |
| 300 | 86.0 |
| 350 | 87.5 |
| 400 | 92.5 |

FIG. 6 indicates the plot of Table 1, i.e., the correlation between input energy and CO₂ decomposition rate. It is seen that the CO₂ decomposition rate is about 70% at the input energy of 100 W, and the decomposition rate becomes large as the input energy increases.

Here, it is noted that the energy required for totally decompose CO₂ into C is 1597.9 [kJ].

CO₂+526.1 [kJ]=CO+O

CO+1071.8 [kJ]=C+O

An introduction of 20 sccm CO₂ means the CO₂ flow with 20×10⁻³/22.4×1/60 (mol/s)=1.488×10⁻⁵ (mol/s). To decompose 20 sccm totally, 1.488×10⁻³ (mol/s)×1597.9 [kJ]=23.78×10⁻³ [kJ/s]=23.78 (W) is needed.

Let (the energy required for totally decomposing introduced CO₂)×CO₂ decomposition rate=A, A becomes 23.78 (W)×0.685=16.29 (W) when the input power and the decomposition rate are 100 (W) and 68.5%, respectively. The efficiency of apparatus is calculated by dividing A by the input energy, and becomes 16.29 (W)/100 (W)=0.1629, that is, 16.29%.

At 150 (W) input energy and 73.0% decomposition rate, A is 23.78 (W)×0.73=17.36 (W). The efficiency of apparatus is 17.36 (W)/150 (W)=0.1157, that is, 11.57%.

At 200 (W) input energy and 81.0% decomposition rate, A is 23.78 (W)×0.81=19.26 (W). The efficiency of apparatus is 19.26 (W)/200 (W)=0.0964, that is. 9.63%.

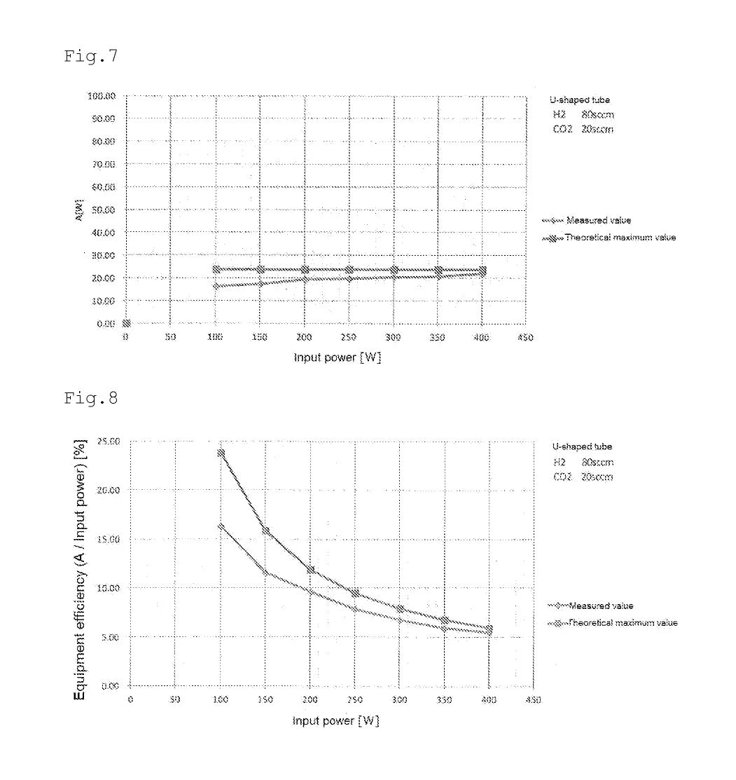

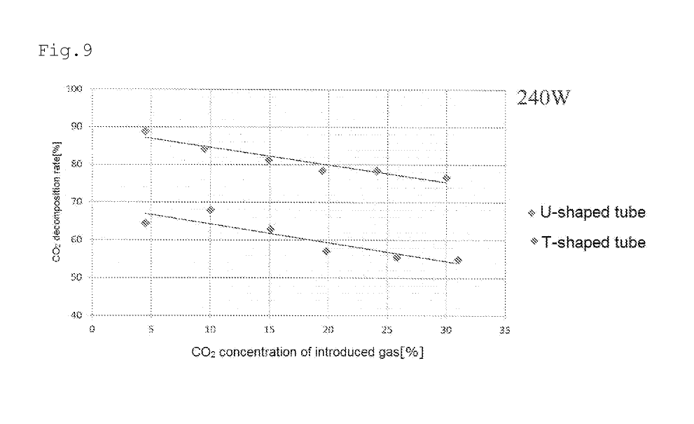

A and the efficiency of apparatus were calculated at the input energy of 250 (W), . . . , 400 (W), and tabulated in Table 2. FIG. 7 is the plot of Table 2, and indicates the correlation between input energy and A (=energy input to totally decompose the introduced CO₂×CO₂ decomposition rate). FIG. 8 is the plot of Table 2, and indicates the correlation between input energy and the efficiency of apparatus.

TABLE 2

| Input | CO₂ decom- | | (Equipment |
|---|---|---|---|
| power | position rate | (A) | efficiency) |
| [W] | [%] | [W] | [%] |
| 100 | 68.5 | 16.29 | 16.29 |
| 150 | 78.0 | 17.36 | 11.57 |
| 200 | 81.0 | 19.26 | 9.63 |
| 250 | 83.0 | 19.74 | 7.89 |
| 300 | 86.0 | 20.45 | 6.82 |
| 350 | 87.5 | 20.81 | 5.94 |
| 400 | 92.5 | 21.99 | 5.50 |

The maximum theoretical value in FIGS. 7 and 8 is explained. The maximum theoretical value means 100% decomposition of CO₂, and let the maximum theoretical value A*, and the maximum theoretical value of apparatus efficiency*.

At the input energy of 100 (W), A*=23.78 (W)×1=28.78 (W). The apparatus efficiency* can be calculated by the ratio of the input power and A*, and 23.78 (W)/100 (W)=0.2378, that is, 23.78%.

Similarly, at the input energy of 150 (W), A*=23.78(W)×1=23.78 (W). The apparatus efficiency* is 23.78 (W)/150 (W)=0.1585, that is, 15.85%.

AT the input energy of 200 (W), A*=23.78 (W) x1=23.78 (W). The apparatus efficiency* is 23.78 (W)/200 (W)=0.1189, that is, 11.89%.

FIG. 9 shows the correlation between gas composition and the rate of CO₂ decomposition. As the CO₂ density in the introduced gas increases, the CO₂ decomposition rate decreases. Clearly from the present experimental results, the decomposition rate of U-shaped tube is higher than that of T-shaped tube.

The CO₂ recycling system uses multiple numbers of CO₂ recycling apparatus, and in this case the vacuum evacuation part of one apparatus is connected to the gas inlet part of the other apparatus. By connecting multiple CO₂ recycling apparatus, the reduction rate of CO₂ becomes much higher.

The present invention aims the synthesis of nano-carbons, and contributes to the effective use and solidifying methods of CO₂ by depositing high value-added nano-carbons. The amount of solidifying CO2 as segregated amorphous fibers is explained.

m₀ (g), the mass of C in the introduced CO₂ gas, is expressed by equation (1), when the mass flow of CO₂ is Q (sccm) and the time of plasma CVD is t (min).

$$\begin{matrix}[ Equation 1 ] & \\ {m}_{0} = \frac{Q \times {10}^{- 3} \times t}{22.4} \times 12 & ( 1 )\end{matrix}$$

When the CO₂ flow is 20 (sccm) and time is 10 minutes, m₀ becomes 0.107 (g) from eq. (1). In addition, when 1 (nm) is the length of amorphous fiber, D(nm) the diameter, d_{c}(μm⁻²) the segregated density, S(cm²) the surface area of substrate, and d_{c}(g/cm³) the density of amorphous carbon, m(g), the mass of solidified C as the segregated fiber, is written by the equation (2).

$$\begin{matrix}[ Equation 2 ] & \\ m = \frac{1}{4} {π ( D \times {10}^{- 7} )}^{2} \times l \times {10}^{- 7} \times {d}_{c} \times {d}_{d} {–10}^{8} \times S & ( 2 )\end{matrix}$$

The calculation were carried out by the following conditions: the length l=900 (nm), the diameter D=45 (nm), segregation density d_{d}=20 (μm⁻²), area of substrate S=0.5 (cm²). The value of density of amorphous carbon reported till now cannot be applied to d_{d}. Theoretical estimation of d_{d} also is difficult, since the ratio of sp² and sp^{a} as well as the content of hydrogen is not known. From these reasons, the actual density was estimated at d_{d}=1.0˜3.0 (g/cm3), which are a little bit smaller than the density of diamond, 3.52 (g/cm³). The calculation of eq. (2) resulted in m=1.43˜4.29×10⁻⁶ (g). The ratio of solidified carbon in the form of segregated fibers is expressed by the equation (3).

$$\begin{matrix}[ Equation 3 ] & \\ S = \frac{m}{{m}_{0}} & ( 3 )\end{matrix}$$

The calculation of eq. (3) resulted in s=1.34˜4.00×10⁻⁵. This result is a rough calculation, and the values are not quite precise. However, the order of the ratio s will not be far from the real value. It is important to increase the value of s, namely, to synthesize as many as amorphous fibers. It is anticipated to increase the amount of synthesized amorphous fibers by increasing the area of substrate and by increasing the amount of gas flow.

### Embodiment 2

Embodiment 2 was carried out by using two CO₂ recycling apparatus with U-shaped reaction tubes (two series configuration). The vacuum evacuation part 4 of the first apparatus was connected to the gas inlet 5 of the next apparatus. CO₂ gas introduced from the gas inlet 5 of the first apparatus is decomposed and reduced by the microwave plasma generated near the folding point 8 of the first apparatus and evacuated from the vacuum evacuation part 4. The vacuum evacuation part 4 of the first apparatus is connected to the gas inlet 5, and consequently the gas introduced from the gas inlet of the next apparatus has somewhat been decomposed and reduced. The microwave plasma near the folding point 8 of the reaction tube, the second decomposition and reduction of CO₂ occurs.

Table 3 compares the experimental results of CO₂ decomposition (reduction) rates obtained from the single CO₂ recycling apparatus and from the one that has two CO₂ recycling apparatus with U-shaped reaction tube. The introduced gas was 20 sccm CO₂ and 80 sccm H₂ as a carried gas. The input power was constant at 100 (W) for all the U-shaped reaction tube. In the case of 2 CO₂ recycling apparatus aligned in series, the input power of 100 (W) is applied to the both of U-shaped reaction tubes. For single CO₂ recycling apparatus, the reduction rate was 68.5%, while for the two CO₂ recycling apparatus connected in series, the reduction rate was 79.5%. From these results, it is clear that CO₂ recycling apparatus connected in series decomposes larger amount of CO₂ than the single one does.

TABLE 3

| | | | | Introduced | | | | |
|---|---|---|---|---|---|---|---|---|
| | | | Total | gas CO₂ | Measurement result | | Reduction | |
| | H2 | CO2 | flow | concentration | Before | After | rate | CO |
| | (sccm) | (sccm) | (sccm) | (%) | plasma | plasma | (%) | (%) |
| 1-stage U-shaped tube (1 station) | 80 | 20 | 100 | 20 | 20 | 6.3 | 68.5 | 14 |
| 2-stage U-shaped tube (2 stations) | 80 | 20 | 100 | 20 | 19.5 | 4 | 79.5 | 21 |

### Other embodiments

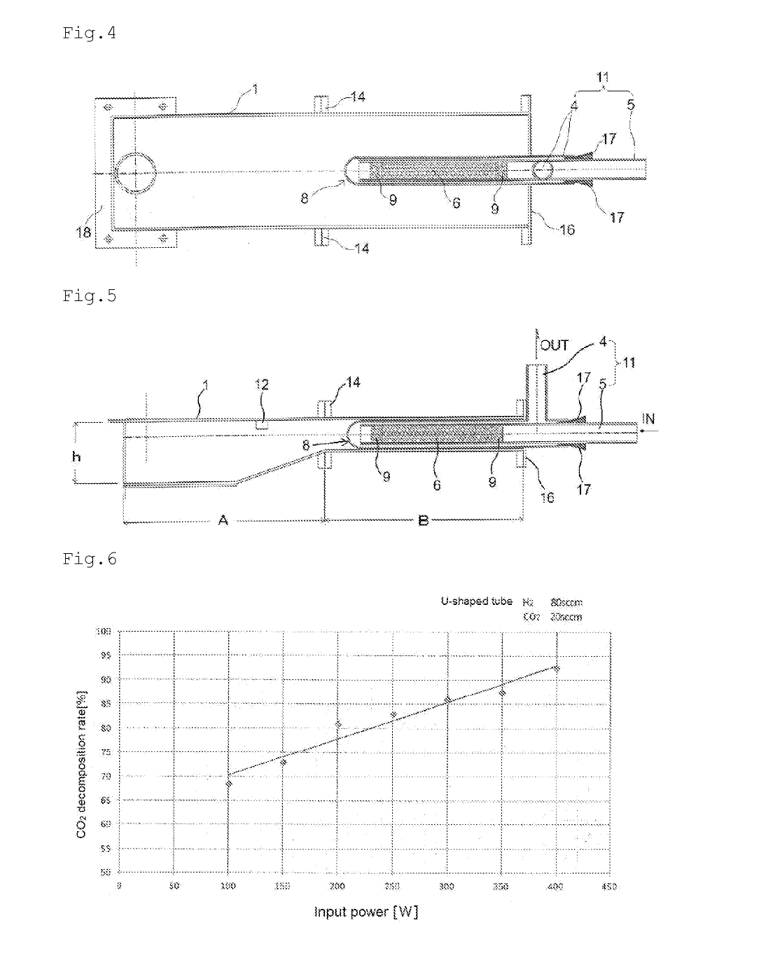

(1) In the above stated embodiments, the U-shaped tube was used as a reaction tube. However, the reaction tube with different diameters is also applicable. In this case, the tube with smaller diameter is connected to the gas inlet, while the one with larger diameter to the vacuum evacuation (see FIGS. 4 and 5). It is advantageous to increase the path of gas flow. Therefore, spiral shaped tube or zigzag tube works effectively as well.

(2) In the above stated embodiments, the microwave guide was used. However, coaxial microwave cable is also applicable. The coaxial microwave cable can be placed near the folding back point of reaction tube.

### INDUSTRIAL APPLICABILITY

The present invention works effectively, as CO₂ recycling apparatus, against CO₂ exhausted from automobiles, ships, public buildings, commercial centers and ordinary families.

### DESCRIPTION OF SYMBOLS

1 Microwave guide; 2 Microwave generator; 3 Reaction tube; 4 Vacuum evacuation tube; 5 Gas inlet; 6 Ceramics heater; 7 Power supply; 8 Folding back point; 10 U-shaped tube; 11 Two-layer tube; 12 Microwave matching device (Stub); 14 Flange; 16 Plate; 17 Stopper; 18 Supporting member; 20 Microwave plasma

1. A CO₂ recycling device that synthesizes either carbon nanotube, carbon onion and/or nano-carbons with using microwave plasma CVD of CO₂ gas which is contained in hydrocarbon gases, the device comprising:
a microwave generator;
a microwave guide;
a reaction tube installed in the above mentioned microwave guide, which is designed to turn back the gas from the gas inlet to the vacuum evacuation part inside the wave guide; and
a ceramics heater at the position of gas inlet,
wherein the device generates the plasma at the reaction tube to produce and deposit multi-wall carbon nanotube, carbon onion and/or nano-carbons.

2. A CO₂ recycling device that synthesizes either carbon nanotube, carbon onion and/or nano-carbons with using microwave plasma CVD of CO₂ gas which is contained in hydrocarbon gases, the device comprising:
a microwave generator;
a coaxial microwave guide;
a reaction tube connected to the above mentioned coaxial microwave guide, which is designed to turn back the gas from the gas inlet to the vacuum evacuation part inside the wave guide; and
a ceramics heater at the position of gas inlet,
wherein the device generates the plasma at the reaction tube to produce and deposit multi-wall carbon nanotube, carbon onion and/or nano-carbons.

3. The CO₂ recycling device according to claim 1, wherein the reaction tube is the U-shaped quartz tube, and one end functions as the gas inlet, while the other as vacuum evacuation tube.

4. The CO₂ recycling device according to claim 1, wherein the reaction tube is composed of two tubes with different diameters, wherein the tube with smaller diameter is connected to the gas inlet, wherein the tube with larger diameter is connected to the vacuum evacuation.

5. The CO₂ recycling device according to claim 3, wherein the reaction tube has the shapes of spiral and zigzag, which enable the gas to travel for a long path.

6. The CO₂ recycling device according to claim 1, wherein the ceramics heater is silicon carbide (SiC).

7. The CO₂ recycling device according to claim 1, wherein the ceramics heater is heated by the microwave irradiation.

8. The CO₂ recycling device according to claim 1, wherein a pressure inside the reaction tube is 100 to 200 Pa.

9. The CO₂ recycling device according to claim 1, wherein the reaction tube is made of transparent quartz, non-transparent quartz, ceramics or metals.

10. The CO₂ recycling device according to claim 1, wherein a size of the microwave guide, a length of which is smaller than 400 mm, the width smaller than 200 mm, and the height smaller than 100 mm.

11. The CO₂ recycling device according to claim 1, wherein the microwave guide that is connected to the microwave matching device.

12. The CO₂ recycling device according to claim 2, wherein the coaxial microwave cable that is connected to the coaxial type three-stub tuner.

13. A CO₂ recycling system is characterized by the multiple use of the CO₂ recycling device according to claim 1, wherein the vacuum evacuation part of one apparatus is connected to the gas inlet part of the other apparatus.

14. The CO₂ recycling system according to claim 13, wherein the system has a CO decomposition ability which decomposes the exhausted carbon monoxide gas (CO) from the first apparatus by the next apparatus.

15. The CO₂ recycling device according to claim 2, wherein the reaction tube is the U-shaped quartz tube, and one end functions as the gas inlet, while the other as vacuum evacuation tube.

16. The CO₂ recycling device according to claim 2, wherein the reaction tube is composed of two tubes with different diameters, wherein the tube with smaller diameter is connected to the gas inlet, wherein the tube with larger diameter is connected to the vacuum evacuation.

17. The CO₂ recycling device according to claim 2, wherein the ceramics heater is silicon carbide (SiC).

18. The CO₂ recycling device according to claim 2, wherein the ceramics heater is heated by the microwave irradiation.

19. The CO₂ recycling device according to claim 2, wherein a pressure inside the reaction tube is 100 to 200 Pa.

20. The CO₂ recycling device according to claim 2, wherein the reaction tube is made of transparent quartz, non-transparent quartz, ceramics or metals.
